(19) United States
(12) Patent Application Publication
(10) Pub. No.: US 2026/0056236 A1
(43) Pub. Date: Feb. 26, 2026

(54) NTERFACE TEST DEVICE WITH LOW POWER SWITCH

(71) Applicants: Hubert Ostmeier, Alexandria, VA (US); EMMANUEL OSTMEIER, Alexandria, VA (US); ANTONI FURLANI ROSA, Florianopolis, SC (US); LUCAS VARELA, GASPAR (BR); FELIPE GASPARETTO KLOPPEL, Sao Jose (BR); ANDRE LUIZ RIOS, Florianopolis (BR)

(72) Inventors: Hubert Ostmeier, Alexandria, VA (US); EMMANUEL OSTMEIER, Alexandria, VA (US); ANTONI FURLANI ROSA, Florianopolis, SC (US); LUCAS VARELA, GASPAR (BR); FELIPE GASPARETTO KLOPPEL, Sao Jose (BR); ANDRE LUIZ RIOS, Florianopolis (BR)

(21) Appl. No.: 18/814,484

(22) Filed: Aug. 24, 2024

(51) Int. Cl. G01R 15/18; G01R 31/66; H01F 27/40; H01F 38/36

(52) U.S. Cl. CPC G01R 15/181; G01R 31/66; H01F 27/402; H01F 38/36; H01F 2027/406

(57) ABSTRACT

A low power switch for use low voltage electrical monitoring circuits provided with signals from a low power instrument transformer such as found in substation facilities that signals via a communication protocol the operational status of potential, current and signal secondary circuits when connected to protection and monitoring devices (or test devices) such as protective relays, fault recorders or any other monitoring and controlling device. The low power switch includes various safety features to prevent damage to the equipment or harm to a technician.

### FIELD OF THE INVENTION

The present invention relates generally to an interface test device with a low power switch and a method that opens a low voltage monitoring circuit, and more specifically to an interface test device with a low power switch and method that opens a low voltage monitoring circuit that is operated by a low power instrument transformer (LPIT) of a high power transformer and/or is configured to prevent accidental damage to the low voltage monitoring circuit during maintenance and/or allows for maintenance of certain components without taking the low voltage monitoring circuit off line.

### BACKGROUND OF THE INVENTION

Most of the components of power system generation, transmission, or distribution facilities, such as transmission lines, step-up and step-down transformers, power breakers and generators are monitored and controlled. The control and monitoring is usually performed by electromechanical or electronic equipment that is able to measure electrical quantities, perform calculations based on pre-defined algorithms and thresholds and actuate the system when necessary. Due to the high voltage, current and power flowing through the high-power components, current transformers, potential transformers, and breakers are employed as an interface between the high-power components and the low-power control and monitoring devices such as a low voltage monitoring circuit. This low voltage monitoring circuit and its associated circuitry are tested by technicians. For example, a technician might test the operation of a low voltage monitoring circuit or its associated circuitry by inserting a test plug into a low power switch and performing various tests. Unfortunately, it is inevitable that mistakes happen during such testing which results in damage to the equipment or harm to the technician. During such testing, the technician might also adjust the low voltage monitoring circuit by changing the parameters of the low voltage monitoring circuit based upon the testing or based upon other factors. Unfortunately, such testing and adjustments take substantial amounts of the technician's time which is expensive. Furthermore, it is typical to perform period maintenance on the circuitry of the low voltage monitoring circuits. In order to perform maintenance on low voltage monitoring circuits, the associated power circuits must be powered down to allow the technician to perform the maintenance since the interface or other components in the low voltage monitoring circuit might otherwise be damaged. These interruptions in operation of the low voltage monitoring circuit and in the power circuit increase the cost of operation. For example, there are costs associated with switching to another power circuit and there are costs associated with the lost usage of the equipment powered by the power circuit.

Modern high voltage switches and power transformers are increasingly installed underground for added safety and in order to save installation space above ground. High voltage conductors need to be continuously monitored. Conventionally inductive voltage transformers (VT) and current transformers (CT) are used to monitor the high voltage conductors. These conventional VTs and CTs are rather bulky and heavy due to iron core coupling to the high voltage conductors and have considerable power draw and thus waste heat generation. Due to their heat generation the VTs and CTs frequently require maintenance and possibly replacement. In underground installations access is limited, typically difficult or impossible.

Accordingly, there is a strong need in the art to improve instrument transformers and associated low voltage monitoring circuits and their associated circuitries to reduce or eliminate the aforementioned drawbacks.

### SUMMARY OF THE INVENTION

The object is achieved by an interface test device for testing a circuit, the interface test device comprising: a low power instrument transformer including a capacitive voltage divider, and a Rogowski coil; a low voltage monitoring circuit receiving signals from the low power instrument transformer; a low power switch including at least one pair of contacts biased towards each other that are electrically connected and in line with the low voltage monitoring circuit configured to open and close the low voltage monitoring circuit powered by the low power instrument transformer; a test circuit connected to the low voltage monitoring circuit before or substantially simultaneously with the low voltage monitoring circuit being opened, wherein the low power switch is configured to provide at least one output based upon at least one parameter of the low voltage monitoring circuit to the test circuit in order to measure the at least one parameter by an external tester connected to the test circuit.

The low power instrument transformer and associated test equipment according to the invention is smaller, lighter less expensive, more reliable, dissipates less heat and requires less maintenance than the prior art and therefore particularly suited for underground installations with limited installation space and for mobile substations assembled in trucks for emergency or temporary use or for military applications and onboard substations in ships or shore installations.

Conventional instrument transformer use inductive voltage transformers (VT) to provide a measuring voltage and current transformers (CT) to provide a measuring current. Low power instrument transformers (LPIT) according to the invention use one capacitive voltage divider per phase to provide a measuring voltage and one Rogowski coil per phase to provide a measuring current.

Low power instrument transformers LPIT with Rogowski coils and capacitve voltage dividers replace iron core instrument transformers in modern underground switches and transformers in substations. The embedded sensors of the LPIT are completely passive (only copper wire). The Rogowski coil measures current and voltage by enveloping the main conductor, unlike for the conventional current transformer no galvanic connection to the main conductor is required. The known current transformers typically generate a measurement current in the range of 1 A to 5 A at 50 V-200 V typically, whereas the Rogowski coils typically generate a measurement current below 1 mA at typically below 1 V. The Rogowski coil measures inductive field of the main conductor, thus measures current in the main conductor. The capacitive voltage divider measures a capacitive field of the main conductor, thus measures voltage in the main conductor and generates a measurement voltage of below 4 V typically.

Directional earth fault protection (ANSI 67 NS) is used in non-earthed grids. The earth fault causes a significant voltage swing and a lot of harmonic content. When no load is connected to the bus bar the current of this harmonic content is very small. Conventional CTs and VTs were not able to detect these harmonics at all, however the inventors found out that they were detectable quite well by the interface test device according to the invention.

The Rogowski coil has advantages over other types of current transformers. It is not a closed loop, because the second terminal is passed back through the center of the toroid core (commonly a plastic or rubber tube) and connected along the first terminal. This allows the coil to be open-ended and flexible, allowing it to be wrapped around a live conductor without disturbing it.

Due to its low inductance, the Rogowski coil can respond to fast-changing currents, down to several nanoseconds. Because it has no iron core to saturate, it is highly linear even when subjected to large currents, such as those used in electric power transmission, welding, or pulsed power applications. This linearity also enables a high-current Rogowski coil to be calibrated using much smaller reference currents. Using a Rogowski coil there is no danger of opening the secondary winding and construction cost is lower.

For larger currents conventional current transformers require an increase of the number of secondary turns, in order to keep the output current constant. Therefore, a Rogowski coil for large current is smaller than an equivalent rating iron core current transformer.

Temperature compensation of the Rogowski coil is simple since a merely a small amount of heat is generated.

Since the Rogowski coil produces a low current in a range 1 mA and below shielded conductors must be used from the Rogowski coil to the low power switch and from the low power switch to shield the current to and from the Rogowski coil against the strong static and electromagnetic fields in the transformer or substation area.

In an advantageous embodiment of the invention the Rogowski coil puts out 450 mV/KA +/−5%

The low power switch includes test blocks and test plugs having four terminals each for each of the three phases of a/c. Two respective terminals are used for the Rogowski coil and two respective terminals are used to for the capacitive voltage divider.

Since the current in the low voltage monitoring circuit in a range below 1 mA is rather small comprehensive EMI shielding has to me applied to the low voltage monitoring circuit, the low power switch, its associated circuitry and the test circuit

Shielded conductors are therefore used at the test blocks and at the test plugs, including a RJ45 shielded ethernet cable at the test plug.

The test blocks have low internal resistance of less than 2 mΩ with contacts closed and with test plugs inserted in order not to distort and conduct the low current signal reliably.

The housings of the test blocks are either made from metal or from a conductive plastic material to in order to reliably shield the electric contacts included therein.

In order to provide reliable and economical connection between the contacts and the RJ45 or the banana plugs printed circuit boards are connected to the contact springs instead of using hand soldered connections since the contact electrodes of the plugs and the banana plugs or RJ45 connectors can be soldered to the printed circuit boards by a wave soldering machine.

### BRIEF DESCRIPTION OF THE DRAWINGS

The invention will now be described in detail based on advantageous embodiments with reference to drawing figures, wherein reference numerals refer to like elements:

FIG. 1 shows a block diagram of an exemplary interface test device with a low power switch according to an embodiment of the invention;

FIG. 2 shows a comparison between a conventional instrument transformer (CIT) and a low power instrument transformer (LPIT) according to the invention;

FIG. 3 shows a low power instrument transformer (LPIT) according to the invention and its components;

FIG. 4 shows a the low power instrument transformer (LPIT) according to the invention and the low power switch according to the invention;

FIG. 5 shows a schematic of a typical test setup including three low power switches according to the invention;

FIG. 6 shows an embodiment of the low power switch including two test plugs and two test blocks where the test plugs are not inserted into the test blocks;

FIG. 7 shows an embodiment of the low power switch where the test plugs are partially inserted into the test blocks;

FIG. 8 shows the low power switch where the test plugs are fully inserted into the test blocks;

FIG. 9 shows a front view of two poles of the test block connected to a low power instrument transformer and to a measuring instrument;

FIG. 10 shows a test block according to the invention with a printed circuit board mounted to the terminals; and

FIG. 11 shows earth fault detected by the test interface according to the invention.

### DETAILED DESCRIPTION

Monitoring of interface test devices for low voltage circuits and systems according to an exemplary embodiment of the invention may be implemented in an automated manner to provide for more continuous and comprehensive monitoring, greater efficiency and safety, reduced costs associated with the monitoring, as well as other advantages. Furthermore, the circuitry used in monitoring and control of an interface test device also may be configured such that maintenance on the low voltage monitoring circuit is able to be performed safely and efficiently without taking the low voltage monitoring circuit off line. With such monitoring circuitry incorporated into the low voltage monitoring circuit, disruptive maintenance may be avoided because the low voltage monitoring circuit does not need to be taken off line during testing and servicing of the low voltage monitoring circuitry which means the servicing is performed without interrupting the low voltage monitoring circuit. This improves efficiency and eliminates the problems that would otherwise be caused by these service interruptions. The interface test device according to an embodiment of the invention is implemented such that a test plug opens the low voltage monitoring circuit. Banana jacks or an additional RJ45 connector at an input side of the switch/plug can allow connection of a temporary merging unit/relay for backup in case of cyber-attack of the main system or for replacement of the main system without interrupting the protection functions or for primary injection test without using the main merging unit.

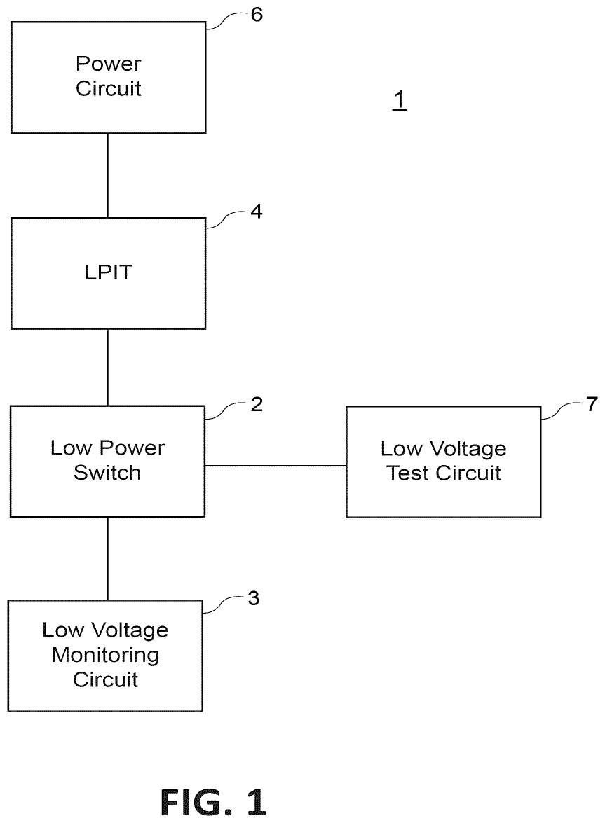

FIG. 1 shows a block diagram of an exemplary interface test device 1 according to an advantageous embodiment of the invention. The interface test device 1 includes a power circuit 6 monitored by a low voltage monitoring circuit 3 receiving signals from a low power instrument transformer 4, a low power switch 2 to connect the low voltage monitoring circuit 3 to a test circuit 7.

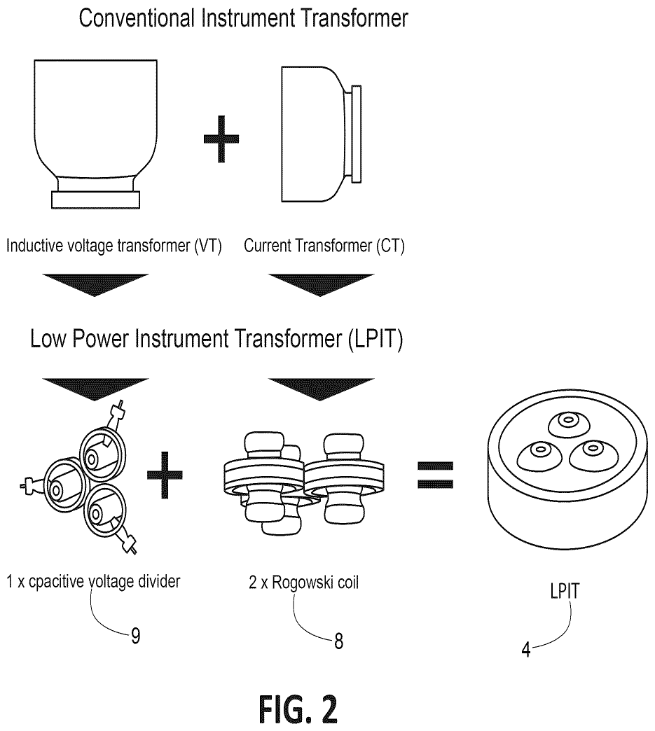

FIG. 2 shows a comparison between a conventional instrument transformer (CIT) and a low power instrument transformer (LPIT) according to the invention showing the reduced installation size enabled by the low power instrument transformer including a Rogowski coil 8 and a capacitive voltage divider 9 for each phase of ac power. The two Rogowski coils 8 per phase shown in FIG. 2 provide redundancy.

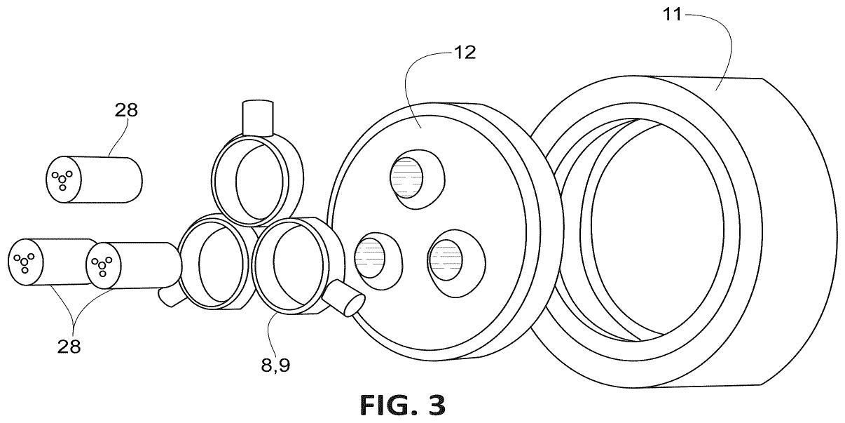

FIG. 3 shows the gas tight low power instrument transformer 4 including the Rogowski coils 8, the capacitive voltage dividers 9, a metal housing 11, a gas tight cast resin partition 12 sealing a vacuum side of the low power instrument transformer from an ambient side of the low power instrument transformer, wherein the Rogowski coils 8 and the capacitive voltage dividers 9 are arranged on the ambient side of the low power instrument transformer.

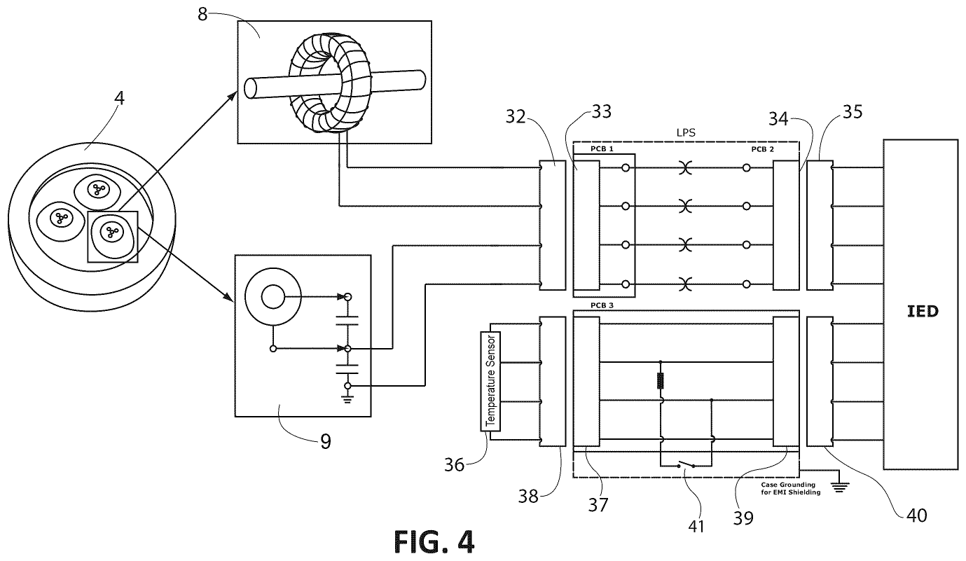

FIG. 4 shows the Rogowski coil 8 and the capacitive voltage divider 9 according to the invention. The Rogowski coil 8 has a current output under 1 mA typically and generates a voltage below 4V typically.

Typical transformation ratios are

| | LPVT (divider | LPVT displacement |
|---|---|---|
| | voltage | current |
| LPCT | measurement) | measurement |
| 130 to 200 mV/kA | 10,000 to 1 or | 10 μA/kV or |
| | 100,000 to 1 | 1 μA/kV |

FIG. 4 also shows a schematic diagram of the low power switch 2 with a first test block 5 including a first circuit board PCB 1 including an internal 4 position connector 33 soldered thereto and connected to the Rogowski coil 8 and the capacitive voltage divider 9 through an external 4-position connector 32 wired to the Rogowski coil 8 and the capacitive voltage divider 9. The plug connector 15 includes a second circuit board PCB 2 including an internal 4-position connector 34 that is connected to an external 4 position connector 35 that is wired to the IED. The test block 5 also includes a third circuit board PCB 3 that is soldered to another internal 4 position connector 37 that is connectable to an external 4 position connector 38 that is wired to a temperature sensor 36. On the other end the third circuit board PCB 3 is soldered to a second internal connector 39 that is connectable to the IED through fourth external connector 40.

Technical specifications of advantageous embodiments of the Test Block 5 are provided in table 1. Technical specifications of advantageous embodiments of the Test Plug 15 are provided in table 2. Technical specifications of advantageous embodiments of the Low Power Switch are provided in table 3.

TABLE 1
DTA—Digital Test Adapter

| Current Withstand | 1.5 A continuously (voltage circuits) | |
|---|---|---|
| | 5 A for 1 second (voltage circuits) | |
| | 5 A continuously (current circuits) | |
| | 30 A for 3 second (current circuits) | |
| Maximum voltage | 125 | V |
| Contact resistance | ≤25 | mΩ |
| Isolation resistance | ≥200 | MΩ |

| | |
|---|---|
| Dielectric Withstand | 600 V RMS for 1 minute between adjacent |
| | contact pairs and between any contact pair |
| | and other metal parts (not applied to current |
| | circuit inputs) |
| Voltage Impulse | 3 positive and 3 negative impulses of 1 kV |
| | peak, 1.2/50 μs, 0.5 J between adjacent |
| | contact pairs and between all contact pairs |
| | and other metal parts |
| Temperature Range | −25 to +70° C. (−13 a + 158° F.), storage |
| | −5 to +45° C. (+23 a + 113° F.), operation |
| Enclosure Protection | IP10 open |
| | IP65 closed and locked |

The switch 41 shown in FIG. 4 is actuated when the test plug 15 is inserted into the test block 5 and changes the resistance of the temperature sensor 36. This change in resistance value can be used to indicate “test mode” or switch the merging unit/relay to test mode. A compatible configuration programming of the merging unit/relay is mandatory to use this function of the low power switch.

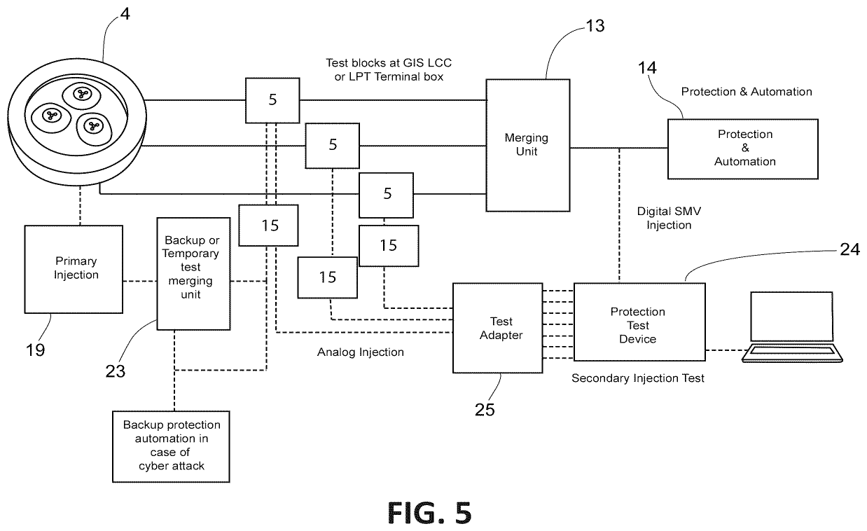

FIG. 5 shows the interface test device 1 including the low power instrument transformer 4, the low power switch 2 including three test blocks 5 and three test plugs 15. The three test blocks 5 are permanently connected to a merging unit 13 which is permanently connected to a protection and automation unit 14. The primary injection unit 19 performs primary injection testing through the temporary test merging unit 23 connectable by the test plugs 15 to the test blocks 5. The test blocks 4 and test blocks 15 have 4 poles per phase. The protection test device 24 performs secondary injection testing through the test adapter 25 by analog injection connectable through the test plugs 15 to the test blocks 5. Banana jacks or an additional RJ45 connector at the input side of the low power switch 2 or the test plug 15 can also be used to connect to the backup merging unit or relay 23 in order to have an alternative protection circuit in case of cyber attack of the main system or for replacement of the main system without interrupting the protection system.

TABLE 2
LPP—Low Power Test Plug

| Current Withstand | 1.5 A continuously | |
|---|---|---|
| | 5 A for 1 second | |
| Maximum voltage | 125 | V |
| Contact resistance | ≤25 | mΩ |
| Isolation resistance | ≥200 | MΩ |

| | |
|---|---|
| Dielectric Withstand | 600 V RMS for 1 minute between adjacent |
| | contact pairs and between any contact pair |
| | and other metal parts |
| | 2.0 kV RMS for 1 minute between contacts |
| | from A side and B side |
| Voltage Impulse | 3 positive and 3 negative impulses of 1 kV |
| | peak, 1.2/50 μs, 0.5 J between adjacent |
| | contact pairs and between all contact pairs |
| | and other metal parts |
| Temperature Range | −25 to +70° C. (−13 a + 158° F.), storage |
| | −25 to +55° C. (−13 a + 131° F.), operation |
| UL94 Flammability Class | V-0 |

TABLE 3
LPS—Low Power Test Switch

| Current Withstand | 10 A continuously | |
|---|---|---|
| | 100 A for 1 second | |
| Maximum voltage | 600 | V |
| Contact resistance | ≤2 | mΩ |
| Isolation resistance | ≥200 | MΩ |

| | |
|---|---|
| Dielectric Withstand | 3.0 kV RMS for 1 minute between adjacent |
| | contact pairs and between any contact pair |
| | and other metal parts |
| | 2.0 kV RMS for 1 minute between open |
| | contacts when the test pin is inserted |
| Voltage Impulse | 3 positive and 3 negative impulses of 5 kV |
| | peak, 1.2/50 μs, 0.5 J between adjacent |
| | contact pairs and between all contact pairs |
| | and other metal parts |
| Temperature Range | −25 to +70° C. (−13 a + 158° F.), storage |
| | −25 to +55° C. (−13 a + 131° F.), operation |
| UL94 Flammability Class | V-0 |
| Enclosure Protection | IP20 without cover |
| | IP50 with dust cover attached |

As further evident from FIG. 4 a first test plug 15 insertable into the first test block 5 includes a second circuit board PCB 2 with an internal 4-position connector 34 soldered thereto that is wired to an external 4 position connector 35 to which the IED is connectable. The low power switch 2 also includes a second test block 5 including a third circuit board PCB 3 including an internal 4 position connector 37 soldered thereto. The internal 4 position connector 37 is connected to an external 4 position connector 38 for PT100 or auxiliary signals that is wired to the temperature sensor 36. All contacts in the test plugs, normally closed NC and normally open NO change their status upon test plug insertion. All conductors in the test blocks withstand 3 kV alternated for 1 minute.

In case of using a relay without merging unit the back up relay can connect directly to the test block 5 or to the test plug 15.

The secondary injection test uses a low power test adapter+a traditional test set or any modern test set able to generate low voltage simulated signals.

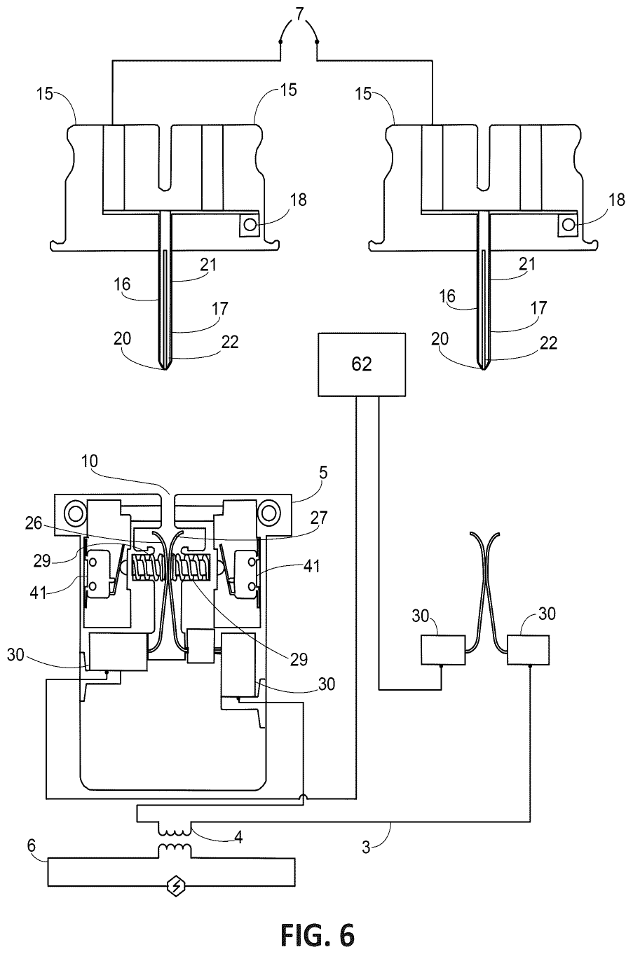

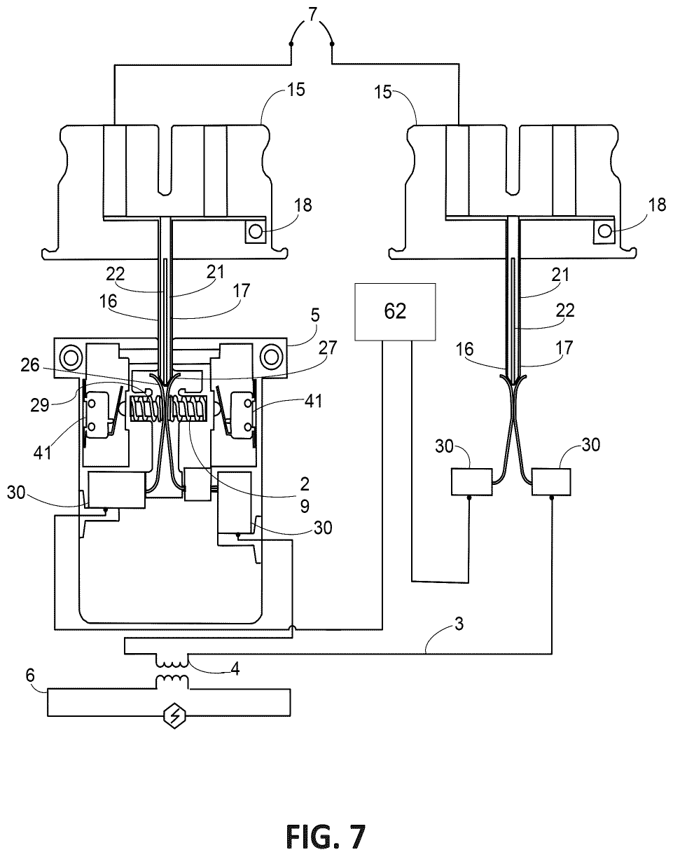

FIG. 6 illustrates an embodiment of the interface test device 1 including a low power switch 2 with two test plugs 15 (also known as test paddles) and two test blocks 5 (also known as test switches or disconnect devices) where the test plugs 15 are not inserted into the test blocks 5. The interface test device 1 of FIG. 7 includes a low voltage monitoring circuit 3, a low power instrument transformer 4, a power circuit 6, a test circuit 7, an aperture 10, two test plug B-side contacts 16, two test plug A-side contacts 17 (test plug B-side contact 16 and test plug A-side contact 17 are collectively referred to as a pair of test plug contacts 16, 17), two shorting bars 18, two fingers 20, two insulators 21, two keying features 22, two test block B-side biased contacts 26, two test block A-side biased contacts 27 (test block B-side biased contact 26 and test block A-side biased contact 27 are collectively referred to as a pair of biased contacts 26, 27 and may be formed from a high-quality silver-plated copper contacts, high-quality gold plated copper contacts or any other suitable material or materials), biasing springs 29, terminals 30, and a piece of equipment 62, e.g. a relay to be tested. The two test blocks are used in series. The second test block, which is only partially shown on the right side of FIG. 6 is configured identical to the fully shown test block. The first and the second test plugs, which are only partially shown on the right side of FIG. 6 and which are identical to the fully illustrated test plug, can be used to isolate and test the piece of equipment 62 or the entire low voltage monitoring circuit 3. The test plugs 15 may be shaped such that only suitable test plugs 15 will mate with the test blocks 5 via apertures 10 with an optional keying feature 22 on fingers 21. This keying feature 22 prevents inadvertent insertion of unsuitable test plugs that result in incorrect measurements and/or incorrect interpretation of important signals for the protection system. Suitable test plugs 15 break the low voltage monitoring circuit 3 and connect the low voltage test circuit 7 with the low voltage monitoring circuit 3 substantially simultaneously. This prevents the low voltage monitoring circuit 3 from ever being interrupted and thus prevents any of the problems that would otherwise result from such an interruption. The test plugs 15 can be inserted into the test blocks 5 for testing potential, current, and signal disconnect links, thereby providing electrical access to all poles on both sides of the test block 5. The simple, safe, and efficient design of the low power switch provides access to in-service signals without interrupting the signal path prior or during test plug insertion.

Additionally, the keying feature 22 assures the various contacts are properly matched such that the test block B-side biased contact 26 is connected to the test plug B-side contact 16 and the test block A-side biased contact 27 is connected to the test plug A-side contact 17. The insulator 21 is disposed between the test plug B-side contact 16 and the test plug A-side contact 17. In other words, the finger 20 includes a keying feature 22 that engages the aperture 10 of the test block 5 such that the finger 20 can only be inserted into the aperture 10 in one orientation and the test plug B-side contact 16 of the test plug 15 connects to the test block B-side biased contact 26 of the test block 5 and the test plug A-side contact 17 of the test plug 15 connects to the test block A-side biased contact 27 of the test block 5 such that a connection with the correct polarity is assured.

The low voltage monitoring circuit 3 is coupled to the power circuit 6 through a low power instrument transformer 4. The pairs of biased contacts 26, 27 are connected to the low voltage monitoring circuit 3 through terminals 30. The test plug 15 includes a finger 21 supporting the pair of test plug contacts 16, 17 configured to connect to the pair of biased contacts 26, 27 of the low voltage monitoring circuit 3. The pair of test plug contacts 16, 17 are connected to the test circuit 7, for testing the low voltage monitoring circuit 3 including the low power instrument transformer 4 and the piece of equipment 62. The test block 5 and the test plug 15 including the finger 21 may be formed from impact resistant insulator material, such as a plastic (e.g. polypropylene or polyethylene) or any other suitable material that will mechanically support and insulate components of the low voltage monitoring circuit 3 and of the test circuit 7. The materials of the test block 5 may be clear so as to assist in maintenance, detection, or sabotage or the like or may be opaque.

The low voltage monitoring circuit 3 operates a low power instrument transformer 4, which is used for monitoring a power circuit 6 and couples the low voltage monitoring circuit 3 to the power circuit 6. This protects the low voltage monitoring circuit 3 from damage because the higher voltages and/or currents in the power circuit 6 would damage or destroy the monitoring and control components in the low voltage monitoring circuit 3 if directly applied. For example, Rogowski coil and a capacitive voltage divider may be used in the low power instrument transformer 4 to monitor the power circuit 6 when the current and/or voltage in the power circuit 6 is too high to directly apply to measuring instruments in the low voltage monitoring circuit 3 or in the test circuit 7. The Rogowski coil is used to produce a reduced current that is accurately proportional to the current in the power circuit 6 that can be conveniently connected to measuring and recording instruments in the low voltage monitoring circuit 3 and in the test circuit 7.

The test block 5 includes an aperture 10 configured to receive a finger 20 of the test plug 15. The test block 5 also houses a pair of biased contacts 26, 27 that act as disconnect links that normally connect the low voltage monitoring circuit 3 to external terminals 30. The terminals 30 may be made of conductive metal material such as brass, copper or any other suitable material. The terminals 30 may be configured to receive standard connectors or other connectors. The finger 20 may be made of impact resistant insulator material such as polypropylene, polyethylene or any other suitable material, and the finger may be configured to insulate against the voltages of the low voltage monitoring circuit 3. As illustrated in FIG. 6, the pair of biased contacts 26, 27 in the test block 5 are in the closed position. In the closed position, the pair of biased contacts 26, 27 are securely pressed together by their own tension and may be additionally pressed together by one or two biasing springs 29 acting substantially against the opening direction of the pair of biased contacts 26, 27 and exerting force from one or both sides to create a constant contact pressure that minimizes internal resistance (e.g., to less than or equal to 2 mΩ). The pair of biased contacts 26, 27 may be spread apart and disconnected from one another by insertion of the finger 20 of the test plug 15 between the pair of biased contacts 26, 27.

FIG. 7 illustrates an embodiment of the low power switch 1 where the test plugs 15 are partially inserted into the test blocks 5. Specifically, the test plugs 15 have been inserted into apertures 10 of the test blocks 5 where the pair of test plug contacts 16, 17 contact the pair of biased contacts 26, 27 but do not cause the pair of biased contacts 26, 27 to separate. The pair of test plug contacts 16, 17 being in contact with the pair of biased contacts 26, 27 ground the low voltage monitoring circuit 3 through the test plug A-side contacts 17 of the test plugs 15 and the shorting bars 18, which act as a safety precaution to protect the monitoring circuit 3 and the test circuit 7 and helps to prevent an electric arc from forming when the contacts 26, 27 are opened.

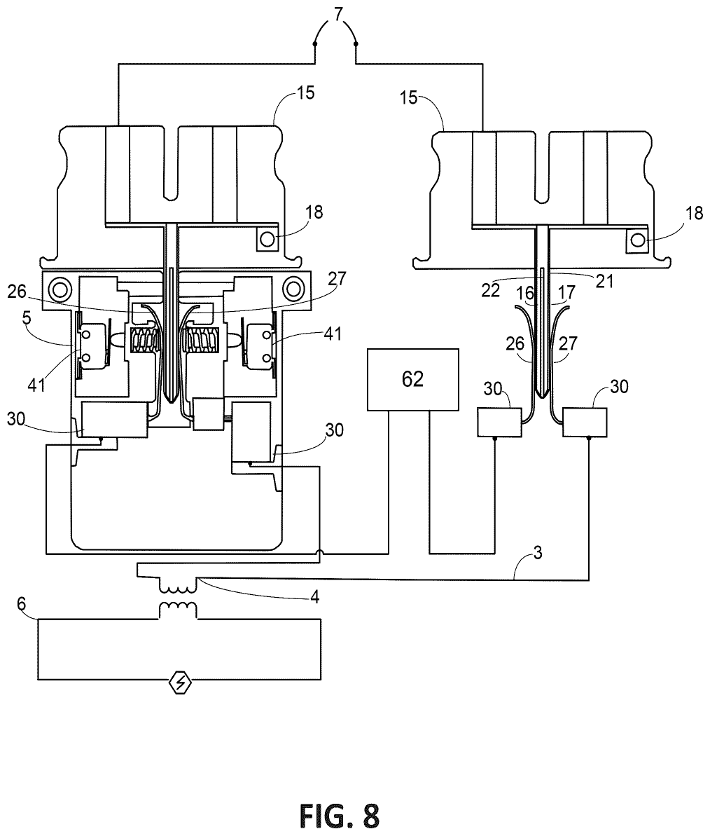

FIG. 8 illustrates the low power switch 2 of FIG. 7 with the test plugs 15 fully inserted into the test blocks 5. The test plug A-side contact 16 connects to the test block A-side biased contact 26 and the test plug B-side contact 17 connects to the test block B-side biased contact 27 of the low voltage circuit 3 and the pair of biased contacts 26, 27 are separated. This means that the test block B-side biased contacts 27 are connected to the test plug B-side contact 17 and thus are grounded by the shorting bar 18 and thus may be used for testing.

Insertion of the test plug 15 farther into the test block 5 as illustrated in FIG. 8 pushes the finger 20 between the pair of biased contacts 26, 27 and separates the pair of biased contacts 26, 27 from each other causing the opening of the low voltage monitoring circuit 3 and thereby connecting to the test circuit 7 and simultaneously isolating the device to be tested in the same motion. The simple, safe, and efficient design of the test plug 15 and the test block 5 provides access to in-service low voltage monitoring and control components 4 and the equipment 62 without interrupting the current path prior or during test plug 15 insertion. Potential and signal links are disconnected by the test plug 15 with high quality electrical insulation. With the test plug 5 inserted as illustrated in FIG. 8, testing and replacement of a low voltage instrument transformer 4 and of the equipment 62 can be safely performed.

The pair of biased contacts 26, 27 automatically closes upon removal of the test plug 15. For example, the biasing springs 29 that press the pair of biased contacts 26, 27 towards each other guarantee that the low voltage monitoring circuit 3 is closed when the testing procedures are finished.

The use of multiple test plugs 15 allows for the testing of portions of the test circuit 7. Alternatively, if the entire test circuit is to be tested, a single test plug may be used.

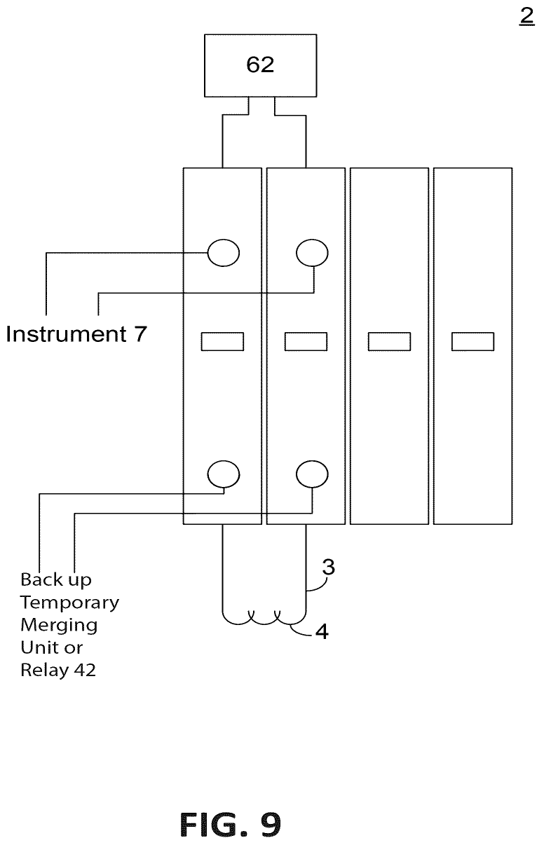

FIG. 9 illustrates a front view of two poles of the test block connected to a low power instrument transformer and to a measuring instrument and banana jack or other connector outputs for connecting a backup/temporary merging unit/relay 42

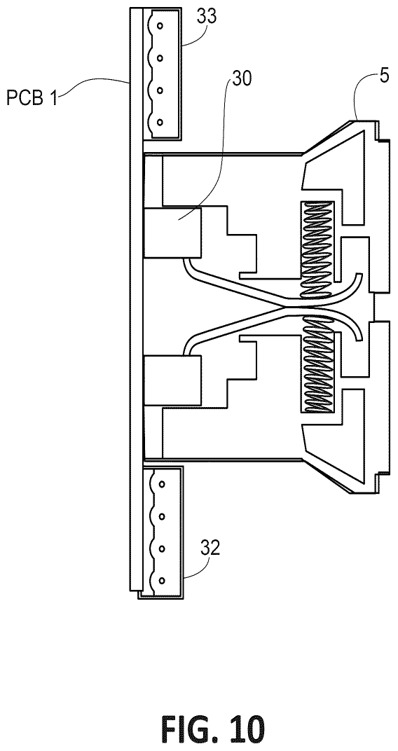

FIG. 10 illustrates a test block 5 according to the invention with printed circuit board 33 bolted to the contact spring terminals 30. Using a printed circuit board in the location instead of individual wiring allows using a wave soldering technique.

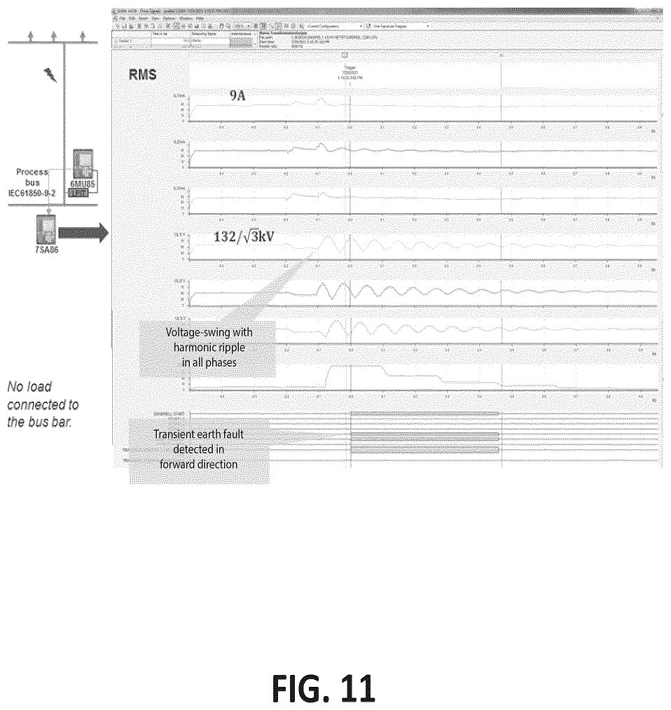

FIG. 11 shows directional earth fault protection (ANSI 67 NS) used in non-earthed grids. The earth fault causes a significant voltage swing and a lot of harmonic content. When no load is connected to the bus bar the current of this harmonic content is very small, but surprisingly they were detectable quite well by the interface test device according to the invention.

The test block 5 can be provided with a metal housing that is closed on all sides or formed with a synthetic material housing that is infused by metal particles that render the metal housing conductive and provide shielding against electromagnetic radiation for components arranged within test block.

FIG. 14 shows a test block 5 shielded by a metal cage on all sides.

Although several embodiments of the present invention and its advantages have been described in detail, it should be understood that changes, substitutions, transformations, modifications, variations, permutations, and alterations may be made therein without departing from the teachings of the present invention, the spirit and the scope of the invention being set forth by the appended claims.

### REFERENCE NUMERALS AND DESIGNATIONS

1 Interface test device
2 Low power switch
3 Low voltage monitoring circuit
4 Low power instrument transformer
5 Test block
6 Power circuit
7 Low voltage test circuit
8 Rogowski coil
9 Capacitive voltage divider
10 Aperture
11 Metal housing
12 Gas tight partition
13 Merging unit
14 Protection automation unit
15 Test plug
16 Test plug B-side contact
17 Test plug A-side contact
18 Shorting bar
19 Primary injection unit
20 Finger
21 Insulator
22 Keying feature
23 Temporary test merging unit
24 Protection test device
25 Test adapter
26 Test block B-side biased contact
27 Test block A-side biased contact
28 Phase contact
29 Biasing Spring
30 Terminal
32 First external 4 position connector
33 First internal 4 position connector
34 Second internal 4 position connector
35 Second external 4 position connector
36 Temperature sensor
37 Third external 4 position connector
38 Third internal 4 position connector
39 Fourth internal 4 position connector
40 Fourth external 4 position connector
41 Switch
42 Temporary merging unit or relay
62 Piece of equipment
PCB1 First circuit board
PCB2 Second circuit board
PCB3 Third circuit board

What is claimed is:

1. An interface test device for testing a high voltage circuit of a high power transformer, the interface test device comprising:
a low power instrument transformer powered by the high voltage circuit and including a capacitive voltage divider, and a Rogowski coil;
a low voltage monitoring circuit provided with signals from the low power instrument transformer;
a low power switch including a test block and a test plug insertable into the test block, the test block including at least one pair of contacts biased towards each other that are electrically connected and in line with the low voltage monitoring circuit configured to open and close the low voltage monitoring circuit provided with signals from the low power instrument transformer; and
a test circuit connected to the low voltage monitoring circuit before or substantially simultaneously with the low voltage monitoring circuit being opened by inserting the test plug into the test block,
wherein the low power switch is configured to provide at least one output based upon at least one parameter of the low voltage monitoring circuit to the test circuit in order to measure the at least one parameter by an external tester connected to the test circuit.

2. The interface test device of claim 1, wherein the low voltage monitoring circuit may be serviced for maintenance without being interrupted.

3. The interface test device of claim 1, wherein the low voltage monitoring circuit and the test circuit are shielded.

4. The interface test device of claim 1, wherein the at least one pair of contacts has a resistance under 2 mΩ.

5. The interface test device of claim 1, wherein the Rogowski coil puts out a current below 1 mA at a voltage below 1V and is installed within a distance of 5 m of the high power transformer operating in a range of 100 kV and above and at 3000 A and above.

6. The interface test device according to claim 1, wherein the test block is shielded by a closed metal cage on all six sides.

7. The interface test device according to claim 1, wherein the test block includes a housing that is made from a synthetic material infused with metal particles rendering the synthetic material conductive and shielding an interior of the test block.

8. The interface test device according to claim 1, wherein the test block includes connectors configured to connect a backup or temporary merging unit or relay.

9. The interface test device according to claim 1, wherein the test block includes a switch that changes a resistance of a circuit of a temperature sensor when the test plug is inserted into the test block, wherein the change of the resistance of the circuit indicates a test mode.
